(19) United States
(12) Patent Application Publication
(10) Pub. No.: US 2024/0035196 A1
(43) Pub. Date: Feb. 1, 2024

(54) METHOD OF SELECTIVE ETCHING OF DIELECTRIC MATERIALS

(71) Applicant: Applied Materials, Inc., Santa Clara, CA (US)

(72) Inventors: Yi-Chiau HUANG, Fremont, CA (US); Eric DAVEY, Mountain View, CA (US)

(21) Appl. No.: 17/874,142

(22) Filed: Jul. 26, 2022

(51) Int. Cl. C30B 25/18; B08B 5/00; B08B 7/00; B08B 7/04; C23C 16/02

(52) U.S. Cl. CPC C30B 25/186; B08B 5/00; B08B 7/0071; B08B 7/04; C23C 16/0236; H01L 21/02068

(57) ABSTRACT

A method includes performing an etch process, including supplying a first process gas and a second process gas onto a surface of a substrate on a substrate support within a processing volume of a processing chamber for a first time duration, wherein the first process gas comprises fluorine-containing gas, and the second process gas comprises nitrogen-containing gas, and performing an anneal process to sublimate by-products formed on the surface of the substrate during the etch process, and supplying the first process gas without supplying the second process gas into the processing volume of the processing chamber for a second time duration.

### BACKGROUND

### Field

Embodiments of the present disclosure generally relate to methods for cleaning a surface of a substrate, and more particularly, to methods for selectively etching oxides (e.g., silicon dioxide (SiO₂)) with respect to other dielectric materials (e.g., silicon nitride (Si₃N₄)).

### Description of the Related Art

Integrated circuits are formed in and on silicon and other semiconductor substrates. In the case of single crystal silicon, substrates are made by growing an ingot from a bath of molten silicon, and then sawing the solidified ingot into multiple substrates. An epitaxial silicon layer may then be formed on the monocrystalline silicon substrate to form a defect free silicon layer that may be doped or undoped. Semiconductor devices, such as transistors, may be manufactured from the epitaxial silicon layer. The electrical properties of the formed epitaxial silicon layer are generally better than the properties of the monocrystalline silicon substrate.

Surfaces of the monocrystalline silicon and the epitaxial silicon layer are susceptible to contamination when exposed to typical substrate fabrication facility ambient conditions. For example, a native oxide layer may form on the monocrystalline silicon surface prior to deposition of the epitaxial layer due to handling of the substrates and/or exposure to ambient environment in the substrate processing facility. The presence of a native oxide layer on the monocrystalline silicon surface negatively affects the quality of an epitaxial layer subsequently formed on the monocrystalline surface. However, as the aspect ratio of features formed of other dielectrics, such as silicon nitride (Si₃N₄) and silicon-oxynitride (SiON), increases, a surface of the substrate to be cleaned may be adjacent to the other dielectrics, which should not be damaged or etched by the cleaning process.

Therefore, there is a need for methods to remove oxides selectively to other dielectrics.

### SUMMARY

Embodiments of the present disclosure provide a method of cleaning a surface of a substrate. The method includes performing an etch process, including supplying a first process gas and a second process gas onto a surface of a substrate on a substrate support within a processing volume of a processing chamber for a first time duration, wherein the first process gas comprises fluorine-containing gas, and the second process gas comprises nitrogen-containing gas, and performing an anneal process to sublimate by-products formed on the surface of the substrate during the etch process, and supplying the first process gas without supplying the second process gas into the processing volume of the processing chamber for a second time duration.

Embodiments of the present disclosure also provide a method of cleaning a surface of a substrate. The method includes performing an etch process, including supplying a first process gas and a second process gas onto a surface of a substrate on a substrate support within a processing volume of a processing chamber for a first time duration, wherein the first process gas comprises fluorine-containing gas, and the second process gas comprises nitrogen-containing gas, and supplying the first process gas without supplying the second process gas into the processing volume of the processing chamber for a second time duration.

Embodiments of the present disclosure further provide a processing system. The processing system includes a processing chamber, and a controller configured to cause a processing method to be performed in the processing chamber, the processing method including performing an etch process, including supplying a first process gas and a second process gas onto a surface of a substrate on a substrate support within a processing volume of a processing chamber for a first time duration, wherein the first process gas comprises fluorine-containing gas, and the second process gas comprises nitrogen-containing gas, and performing an anneal process to sublimate by-products formed on the surface of the substrate during the etch process, and supplying the first process gas without supplying the second process gas into the processing volume of the processing chamber for a second time duration.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of this disclosure and are therefore not to be considered limiting of its scope, for the disclosure may be applied to other equally effective embodiments.

FIG. 1A is a cross-sectional view of an example processing chamber, according to one or more embodiments. FIG. 1B is an enlarged view of a portion of the processing chamber of FIG. 1A. FIG. 1C is an enlarged cross-sectional view of an example substrate support according to one or more embodiments.

FIG. 2 depicts a process flow diagram of a method of removing oxides (e.g., silicon oxide (SiO₂)) from a surface of a substrate according to at least one embodiment of the present disclosure.

FIG. 3 depicts an example of oxide removal and nitride removal during an etch cycle time.

FIGS. 4A and 4B depict an example of oxide removal and nitride removal during an etch cycle time. FIG. 4C depicts an example of etch selectivity of oxides with respect to nitrides.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to methods and systems for selectively removing oxides (e.g., silicon oxide (SiO₂)) from a surface of a substrate with respect to other dielectric materials (e.g., silicon nitride (Si₃N₄)). An etch process according to the methods described herein utilizes a fluorine-containing primary etchant gas, such as hydrogen fluoride (HF) gas, and a fluorine-containing catalyst gas, such as gaseous ammonia (NH₃). During the etch process, the supply of the fluorine-containing catalyst gas is reduced or eliminated. Modulation of the time duration of the reduced or eliminated supply of the fluorine-containing catalyst gas modulates etch selectivity of oxides (e.g., silicon oxide (SiO₂)) with respect to other dielectric materials (e.g., silicon nitride (Si₃N₄)), and thus the etch selectivity can be optimized by appropriately adjusting the time duration of the reduced or eliminated supply of the fluorine-containing catalyst gas during an etch process.

The methods described herein are selective and conformal, and useful for cleaning high aspect ratio features. Further, the methods described herein enable high-throughput cleaning of high aspect ratio features with minimal loss of dielectric materials (e.g., silicon nitride (Si₃N₄) and silicon-oxynitride (SiON), sidewall spacers and hardmasks). In addition, the methods described herein enable isotropic and conformal cleaning of features whereby native oxide on, for example, the sidewall (110) silicon surfaces, are removed in addition to the native oxide on the (100) silicon surfaces. After cleaning, the resultant substrate can be used for further processing such as epitaxial growth and/or chemical vapor deposition of Si- and/or Ge-containing layers.

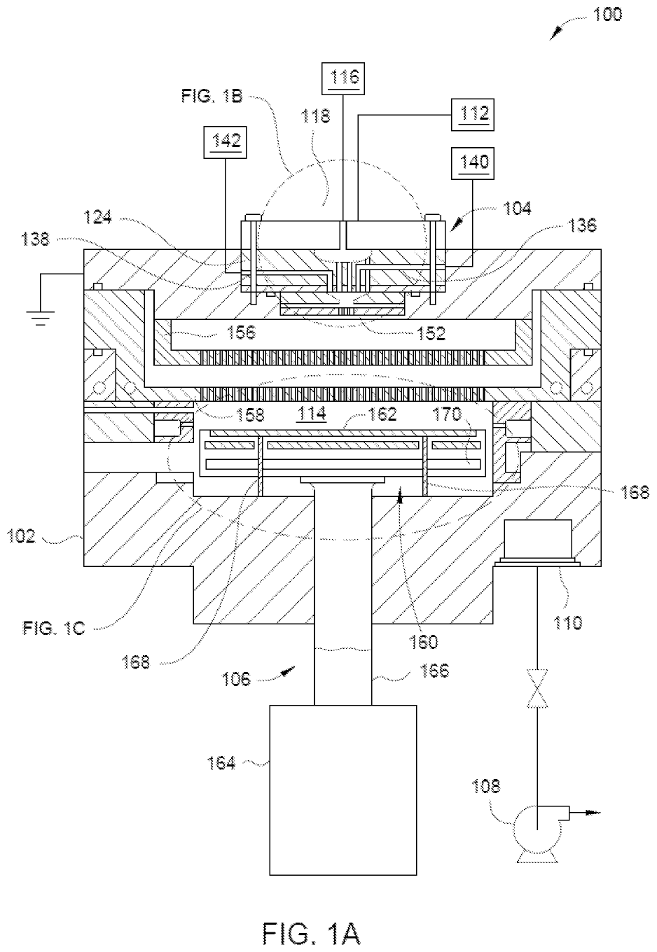

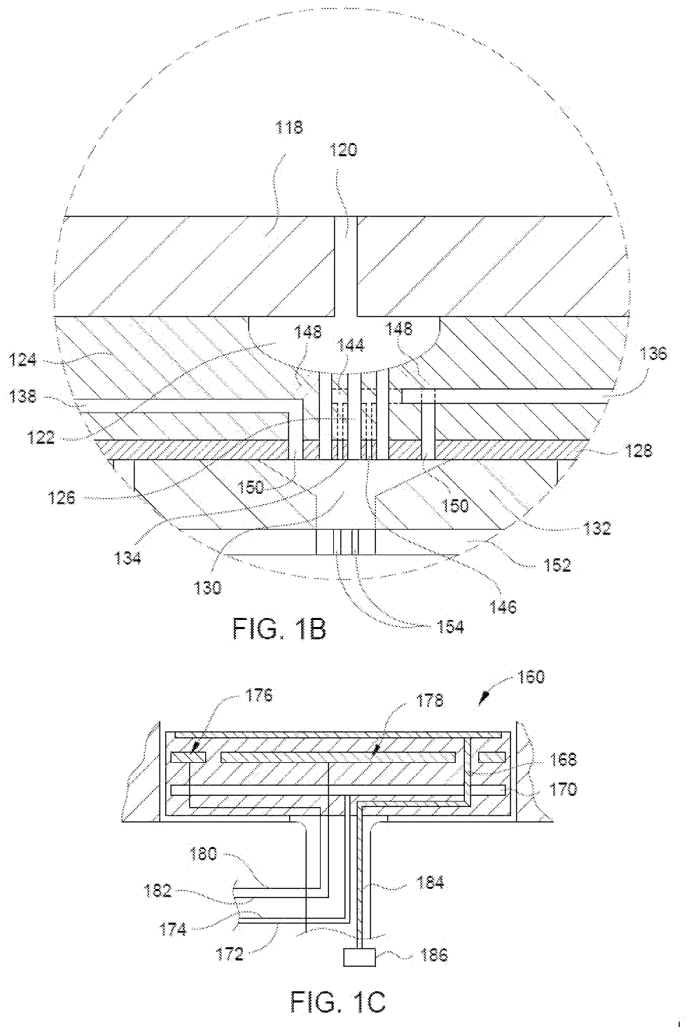

FIG. 1A is a cross-sectional view of an example processing chamber 100, according to one or more embodiments, which is adapted to perform cleaning processes as detailed below. FIG. 1B is an enlarged view of a portion of the processing chamber 100 of FIG. 1A. An example processing chamber that can be adapted to perform the cleaning processes described herein includes Clarion™ chamber, which is available from Applied Materials, Inc., of Santa Clara, California. Chambers from other manufacturers may also be used.

The processing chamber 100 includes a chamber body 102, a lid assembly 104, and a support assembly 106. The lid assembly 104 is disposed at an upper end of the chamber body 102, and the support assembly 106 is at least partially disposed within the chamber body 102. A vacuum system can be used to remove gases from the processing chamber 100. The vacuum system includes a vacuum pump 108 coupled to a vacuum port 110 disposed in the chamber body 102. The processing chamber 100 also includes a controller 112 for controlling processes within the processing chamber 100.

The lid assembly 104 includes a plurality of stacked components that can provide precursor gases to a processing volume 114 within the processing chamber 100. A gas source 116 is coupled to the lid assembly 104 via a first plate 118. The gas source 116 can be configured to provide a non-reactive gas such as a noble gas. Illustrative, but non-limiting, examples of non-reactive gases include helium (He), neon (Ne), argon (Ar), krypton (Kr), and/or xenon (Xe), or other non-reactive gas(es).

Referring to FIG. 1B, an opening 120 allows gas(es) to flow from the gas source 116 to a volume 122 formed in a second plate 124 of the lid assembly 104. A central conduit 126, which is formed in the second plate 124, is adapted to provide the gases from the volume 122 through a third plate 128 to a mixing chamber 130 formed in a fourth plate 132 of the lid assembly 104. The central conduit 126 communicates with the mixing chamber 130 through an opening 134 in the third plate 128. The opening 134 may have a diameter less than, greater than or the same as a diameter of the central conduit 126. In the embodiment of FIG. 1B, the opening 134 has diameter the same, or substantially the same, as the central conduit 126.

The second plate 124 also includes a plurality of inlets 136 and 138 that are configured to provide gases to the mixing chamber 130. The inlet 136 is coupled to a first gas source 140 and the inlet 138 is coupled to a second gas source 142. The first gas source 140 and the second gas source 142 may contain process gases as well as non-reactive gases, for example noble gases such as argon and/or helium, utilized as a carrier gas. The first gas source 140 may contain a nitrogen-containing gas (e.g., ammonia (NH₃)). The second gas source 142 may contain fluorine-containing gases as well as hydrogen containing gases. In one example, the second gas source 142 may contain hydrogen fluoride (HF). The first gas source 140 and/or the second gas source 142 can contain one or more non-reactive gases.

The first gas source 140 and/or the second gas source 142 may include one or more ampoules, one or more bubblers, and/or one or more liquid vaporizers configured to provide a process gas. For example, in cases where a liquid precursor (e.g., hydrogen fluoride (HF)) is used, the first gas source 140 and/or the second gas source 142 may include a liquid vaporizer in fluid communication with a liquid precursor source (not shown). The liquid vaporizer can be used for vaporizing liquid precursors to be delivered to the lid assembly 104. While not shown, it is contemplated that the liquid precursor source may include, e.g., one or more ampoules of precursor liquid and solvent liquid, a shut-off valve, and a liquid flow meter (LFM). As an alternative to the liquid vaporizer, a bubbler may be used to deliver the liquid precursor(s) to the chamber. In such cases, an ampoule of liquid precursor is connected to the process volume of the chamber through a bubbler.

As illustrated in FIG. 1B, in some configurations, the inlet 136 is coupled to the mixing chamber 130 through a cylindrical channel 144 (shown in phantom) and a plurality of holes 146 formed in the third plate 128. The inlet 138 is coupled to the mixing chamber 130 through a cylindrical channel 148 (shown in phantom) and a plurality of holes 150 formed in the third plate 128. The holes 146, 150 formed in the third plate 128 are generally sized so that they enable a uniform flow of gases, which are provided from their respective gas source 140, 142, into the mixing chamber 130. In one configuration, the holes 150 have a diameter that is less than a width of the opening defined by the opposing sidewalls of the cylindrical channel 148 formed in the second plate 124. The holes 150 are typically distributed around the circumference of the center-line of the cylindrical channel 148 to provide uniform fluid flow into the mixing chamber 130. In one configuration, the holes 146 have a diameter that is less than a width of the opening defined by the opposing sidewalls of the cylindrical channel 144 formed in the second plate 124. The holes 146 are typically distributed around the circumference of the center-line of the cylindrical channel 144 to provide uniform fluid flow into the mixing chamber 130.

The inlets 136 and 138 provide respective fluid flow paths laterally through the second plate 124, turning toward and penetrating through the third plate 128 to the mixing chamber 130. The lid assembly 104 also includes a fifth plate or first gas distributor 152, which may be a gas distribution plate, such as a showerhead, where the various gases mixed in the lid assembly 104 are flowed through perforations 154 formed therein. The perforations 154 are in fluid communication with the mixing chamber 130 to provide flow pathways from the mixing chamber 130 through the first gas distributor 152. Referring back to FIG. 1A, a blocker plate 156 and a gas distribution plate, such as a second gas distributor 158, which may be a gas distribution plate, such as a showerhead, is disposed below the lid assembly 104.

The support assembly 106 may include a substrate support 160 to support a substrate 162 thereon during processing. The substrate support 160 may be coupled to an actuator 164 by a shaft 166 which extends through a centrally-located opening formed in a bottom of the chamber body 102. The actuator 164 may be flexibly sealed to the chamber body 102 by bellows (not shown) that prevent vacuum leakage around the shaft 166. The actuator 164 allows the substrate support 160 to be moved vertically within the chamber body 102 between a processing position and a loading position. The loading position is slightly below the opening of a tunnel (not shown) formed in a sidewall of the chamber body 102.

The substrate support 160 has a flat, or a substantially flat, substrate supporting surface for supporting a substrate 162 to be processed thereon. The substrate support 160 may be moved vertically within the chamber body 102 by the actuator 164, which is coupled to the substrate support 160 by the shaft 166. For some operations, the substrate support 160 may be elevated to a position in close proximity to the lid assembly 104 to control the temperature of the substrate 162 being processed. As such, the substrate 162 may be heated via radiation emitted from the second gas distributor 158, or another radiant source, or by convection or conduction from the second gas distributor 158 through an intervening gas. In some process steps, the substrate 162 may be disposed on lift pins 168 to perform additional thermal processing steps, such as performing an annealing step.

FIG. 1C is an enlarged cross-sectional view of the substrate support 160 of FIG. 1A. The substrate support 160 includes a thermal control plenum 170 in fluid communication with a fluid supply conduit 172 and a fluid return conduit 174. Each of the fluid supply conduit 172 and the fluid return conduit 174 is disposed through the shaft 166. The thermal control plenum 170 may be a cooling feature for the substrate support 160 by circulating a cooling fluid through the fluid supply conduit 172, into the thermal control plenum 170, and out through the fluid return conduit 174.

The substrate support 160 may also include a plurality of heaters. The plurality of heaters, in this embodiment, includes a first heater 176 and a second heater 178. The first heater 176 and the second heater 178 are disposed in a substantially coplanar relationship within the substrate support 160 at a location to enable thermal coupling between the heaters and the substrate supporting surface. The first heater 176 is disposed at a periphery of the substrate support 160, and the second heater 178 is disposed in a central area of the substrate support 160, to provide zonal temperature control. Each of the first heater 176 and the second heater 178 may be a resistive heater that is coupled to one or more power sources (not shown) by respective power conduits 180 and 182, each disposed through the shaft 166.

In operation, temperature control may be provided by concurrent operation of the thermal control plenum 170, the first heater 176, and the second heater 178. The thermal control plenum 170 may be supplied with a cooling fluid, as described above, and power may be provided to the first heater 176 and the second heater 178, as resistive heaters. In this way, separate control circuits may be tuned to provide fast response for one item, for example the first heater 176 and the second heater 178, and slower response for the thermal control plenum 170, or vice versa. At a minimum, different control parameters may be applied to the thermal control plenum 170, the first heater 176, and the second heater 178 to accomplish an optimized, zonal temperature control system.

As shown in FIG. 1C, a separate lift member 184 may be included in the support assembly 106. A recess may be provided in the substrate supporting surface to accommodate the lift pins 168 of the lift member 184 when the substrate rests on the substrate supporting surface. The lift member 184 may be coupled to a lift actuator 186 by an extension of the lift member 184 disposed through the shaft 166. The lift actuator 186 may move the lift member 184 vertically to lift the substrate 162 off the substrate supporting surface toward the first gas distributor 152. The lift member 184 may be a hoop, such as an open hoop or a closed hoop, which may be U-shaped, circular, horseshoe-shaped, or any convenient shape. The lift member 184 has a thickness to provide structural strength when lifting a substrate. In one example, the lift member 184 is made of a ceramic material and is about 1 mm thick.

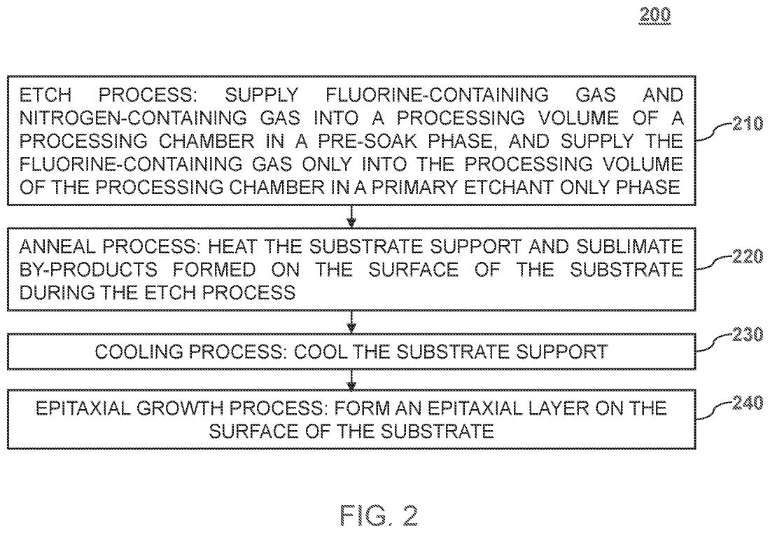

FIG. 2 depicts a process flow diagram of a method 200 of removing oxides (e.g., silicon oxide (SiO₂)) from a surface of a substrate with high selectivity with respect to other dielectric materials (e.g., silicon nitride (Si₃N₄)), according to at least one embodiment of the present disclosure. It should be noted that although the method illustrated in FIG. 2 is described sequentially, other process sequences that include one or more operations that have been omitted and/or added, and/or has been rearranged in another desirable order, fall within the scope of the embodiments of the disclosure provided herein.

The method 200 may be performed in a processing chamber, such as the processing chamber 100 shown in FIGS. 1A and 1B.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 200 begins with an etch process in block 210. The etch process may be an isotropic and conformal dry etch process. In the etch process, one or more process gases including fluorine-containing gas, such as hydrogen fluoride (HF) gas, and nitrogen-containing gas, such as gaseous ammonia (NH₃), trimethylamine (TMA), triethylamine (TEA), ammonia (NH₃), nitrogen monoxide (NO), or nitrogen dioxide (NO₂) are supplied onto a substrate disposed on a substrate support, such as the substrate support 160, within a processing volume, such as the processing volume 114, of the processing chamber. The fluorine-containing gas, such as hydrogen fluoride (HF) gas, may be routed through an inlet from one gas source, such as the inlet 136 from the first gas sourced 140, and the nitrogen-containing gas, such as gaseous ammonia (NH₃), may be routed from another inlet from another gas source, such as the inlet 138 from the second gas source 142. In some embodiments, a non-reactive process gas, such as helium (He), neon (Ne), argon (Ar), krypton (Kr), and/or xenon (Xe), can be used with one or more process gases as a carrier gas and/or a purge gas during substrate processing.

During the etch process, the substrate support is maintained at a low temperature of about 10° C. and about 15° C., for example, about 14° C., by, for example, circulating a temperature control fluid through the thermal control plenum 170. The substrate support may be powered to provide radial temperature control. The processing chamber is maintained at a pressure of between less than about 1° Torr and about 20° Torr, for example, about 5° Torr. The fluorine-containing gas, such as hydrogen fluoride (HF) gas, is supplied as a primary etchant for etching oxides. The nitrogen-containing gas, such as gaseous ammonia (NH₃), is supplied as a catalyst that catalyzes conversion of silicon oxide (SiO₂) and silicon nitride (Si₃N₄) to by-products on a surface of the substrate, such as salts formed of ammonium fluorosilicate ((NH₄)₂SiF₆). In some embodiments, the substrate support is maintained at a temperature of about 40° C. and about 50° C. during the etch process.

The etch process begins with a pre-soak phase, in which both of the fluorine-containing primary etchant gas and the fluorine-containing catalyst gas are supplied, followed by a primary etchant only phase, in which the supply of the fluorine-containing catalyst gas is stopped or reduced. In some embodiments, the pre-soak phase lasts for between about 5 seconds and about 60 seconds, for example, about 15 seconds, and the primary etchant only phase lasts for between about 5 seconds and about 60 seconds, for example, about 20 seconds, in one etch cycle time of about 15 seconds and about 20 seconds.

The fluorine-containing primary etchant gas, such as hydrogen fluoride (HF) gas, may be supplied at a flow rate of between about 2 sccm and about 40 sccm, for example, about 5 sccm during the pre-soak phase and the primary etchant only phase. The fluorine-containing catalyst gas, such as gaseous ammonia (NH₃), may be supplied at a flow rate of between about 5 sccm and about 50 sccm, for example, about 12.5 sccm during the pre-soak phase and not supplied during the primary etchant only phase. In some embodiments, during the primary etchant only phase, the fluorine-containing catalyst gas, such as such as gaseous ammonia (NH₃), is supplied at a lower flow rate during the pre-soak phase (for example, less than about 10 sccm).

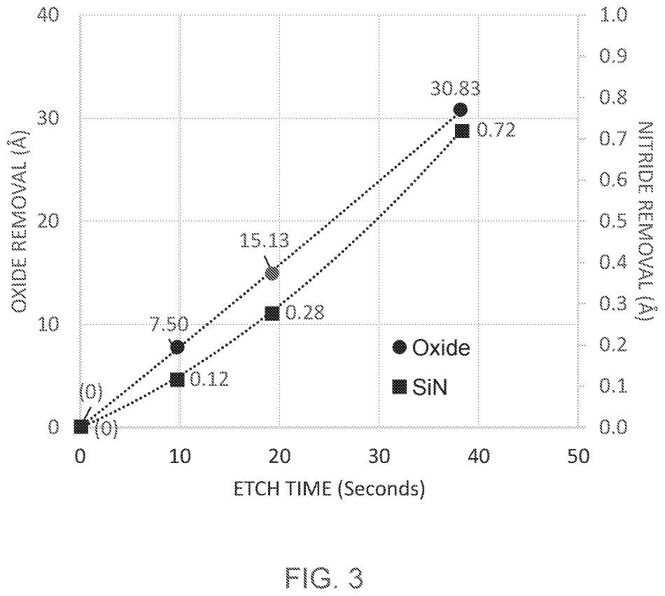

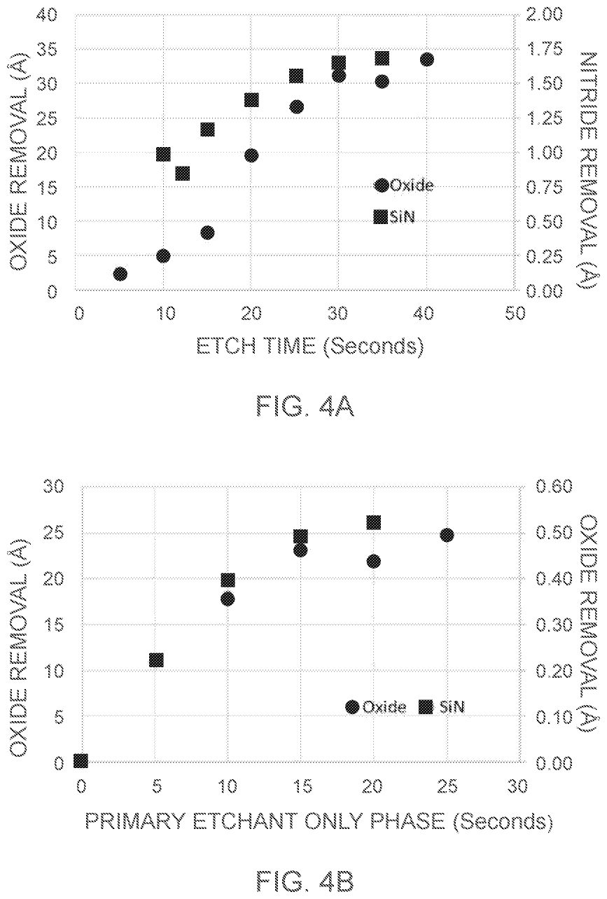

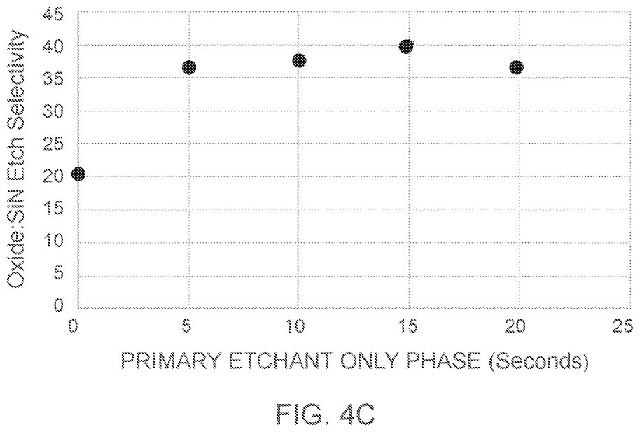

Conventionally, an etch process to remove oxides utilizes both fluorine-containing gas, such as hydrogen fluoride (HF) gas, and nitrogen-containing gas, such as gaseous ammonia (NH₃). The inventors have shown that, as illustrated in FIG. 3, during an etch cycle time of about 38 seconds, an etch rate of oxides (e.g., silicon oxide (SiO₂)) stays substantially constant (i.e., the oxide removal is substantially linear in etch time), and an etch rate of nitrides (e.g., silicon nitride (Si₃N₄)) increases (i.e., the slope of the nitride removal increases in etch time). That is, the etch selectivity of the oxides with respect to the nitrides decreases as the etch process proceeds. The inventors have also shown that, as illustrated in FIGS. 4A and 4B, when a flow of the nitrogen-containing gas, such as gaseous ammonia (NH₃), is stopped or reduced during the etch cycle time (e.g., at about 15 seconds from the beginning of the cycle time in FIG. 4A), an etch rate of the nitrides does not increase (i.e., the slope of the nitride removal does not increase) in the primary etchant only phase after the nitrogen-containing gas is stopped.

The etch selectivity of oxides with respect to nitrides varies as time duration of the primary etchant only phase per etch cycle time. In the example shown in FIG. 4C, the etch selectivity varies between about 20 and 40, and a maximum value of about 40 when the primary etchant only phase lasts for about 15 seconds per etch cycle time of between 25 seconds and about 30 seconds.

In some embodiments, the etch process in block 210 is based on a SiConi™ etch process. A SiConi™ etch process is a remote plasma assisted dry etch process, in which fluorine-containing gas includes nitrogen trifluoride (NF₃) plasma. During the etch process, the substrate support may be maintained at a temperature of between about 30° C. and about 50° C., for example, about 35° C.

In block 220, an anneal process is performed to sublimate the by-products formed on a surface of the substrate in the etch process in block 210. The substrate support is heated to a higher temperature of above about 80° C., for example, at or above about 100° C. The processing chamber is maintained at a pressure of between about 1° Torr and about 10° Torr, for example, about 3° Torr. In some embodiments, thermal energy is provided via a radiant, convective, and/or conductive heat transfer process. In the anneal process, the by-products formed in block 210, such salts formed of ammonium fluorosilicate ((NH₄)₂SiF₆), are sublimated and removed from the substrate.

In block 230, a cooling process is performed to cool the substrate support to the lower etch temperature of about 10° C. and about 15° C., for example, about 14° C., and a cycle of the etch process in block 220 and the anneal process in block 230 is repeated until desired removal of oxides is achieved. The temperature of the substrate support can be cycled between the higher sublimation temperature in block 220 and the lower etch temperature in block 210, for example, by positioning the substrate support closer to the lid in the anneal process in block 220 and farther from the lid in the etch process in block 210. In some examples, the cycle of the etch process in block 220 and the anneal process in block 230 is repeated for two or three times.

In block 204, an epitaxial growth process is performed to form an epitaxial layer on the cleaned surface of the substrate. The epitaxial layer may be a crystalline silicon, germanium, or silicon germanium, or any suitable semiconductor material such as a Group III-V compound or a Group II-VI compound. The epitaxial growth process in block 204 may be performed in a vapor phase epitaxy deposition chamber, for example an Epi chamber available from Applied Materials, Santa Clara, California, such as Centura™ Epi chamber.

The method described herein enable selective removal of undesired oxides (e.g., silicon oxide (SiO₂)) on a surface of a substrate having high aspect ratio device features. An etch process according to the methods described herein is conformal and selective to other dielectric materials (e.g., silicon nitride (Si₃N₄)). The etch selectivity can be optimized by appropriately adjusting time duration of reduced or eliminated supply of fluorine-containing catalyst gas, such as such as gaseous ammonia (NH₃) while fluorine-containing primary etchant gas, such as hydrogen fluoride (HF) gas, is continuously supplied.

The methods described herein enable high-throughput cleaning of high aspect ratio features with minimal loss of dielectric materials (e.g., silicon nitride (Si₃N₄) and silicon-oxynitride (SiON), sidewall spacers and hardmasks). In addition, the methods described herein enable isotropic and conformal cleaning of features whereby native oxide on, for example, the sidewall (110) silicon surfaces, are removed in addition to the native oxide on the (100) silicon surfaces. After cleaning, the resultant substrate can be used for further processing such as epitaxial growth and/or chemical vapor deposition of Si- and/or Ge-containing layers.

While the foregoing is directed to embodiments of the present disclosure, other and further embodiments of the disclosure may be devised without departing from the basic scope thereof, and the scope thereof is determined by the claims that follow.

What is claimed is:

1. A method of cleaning a surface of a substrate, comprising:
performing an etch process, comprising:
supplying a first process gas and a second process gas onto a surface of a substrate on a substrate support within a processing volume of a processing chamber for a first time duration, wherein the first process gas comprises fluorine-containing gas and the second process gas comprises nitrogen-containing gas; and
supplying the first process gas without supplying the second process gas into the processing volume of the processing chamber for a second time duration; and
performing an anneal process to sublimate by-products formed on the surface of the substrate during the etch process.

2. The method of claim 1, wherein
the fluorine-containing gas comprises hydrogen fluoride (HF), and
the nitrogen-containing gas gaseous comprises ammonia (NH₃).

3. The method of claim 1, wherein
the first time duration is between 5 seconds and 60 seconds, and
the second time duration is between 5 seconds and 60 seconds.

4. The method of claim 1, wherein
a flow rate of the fluorine-containing gas is between 2 sccm and 40 sccm, and
a flow rate of the nitrogen-containing gas is between 5 sccm and 50 sccm.

5. The method of claim 1, wherein
the processing chamber is maintained at a first pressure of between less than 1° Torr and 20° Torr during the etch process, and at a second pressure of between 1° Torr and 10° Torr during the anneal process.

6. The method of claim 1, wherein
the substrate support is maintained at a first temperature of 10° C. and 15° C. during the etch process, and at a second temperature of above 80° C. during the anneal process.

7. The method of claim 6, further comprising:
cooling the substrate support to the first temperature; and
repeating the etch process and the anneal process.

8. The method of claim 1, further comprising forming a film on the substrate by a vapor phase epitaxy process.

9. A method of cleaning a surface of a substrate, comprising:
performing an etch process, comprising:
supplying a first process gas and a second process gas onto a surface of a substrate on a substrate support within a processing volume of a processing chamber for a first time duration, wherein the first process gas comprises fluorine-containing gas, and the second process gas comprises nitrogen-containing gas; and
supplying the first process gas without supplying the second process gas into the processing volume of the processing chamber for a second time duration.

10. The method of claim 9, wherein
the fluorine-containing gas comprises hydrogen fluoride (HF), and
the nitrogen-containing gas gaseous comprises ammonia (NH₃).

11. The method of claim 9, further comprising:
performing an anneal process to sublimate by-products formed on the surface of the substrate during the etch process.

12. The method of claim 11, wherein
the first time duration is between 5 seconds and 60 seconds,
the second time duration is between 5 seconds and 60 seconds,
a flow rate of the fluorine-containing gas is between 2 sccm and 40 sccm,
a flow rate of the nitrogen-containing gas is between 5 sccm and 50 sccm,
the processing chamber is maintained at a first pressure of between less than 1° Torr and 20° Torr during the etch process, and at a second pressure of between 1° Torr and 10° Torr during the anneal process.

13. The method of claim 11, wherein
cooling the substrate support to a first temperature; and
repeating the etch process and the anneal process, wherein
the substrate support is maintained at the first temperature of 10° C. and 15° C. during the etch process, and at a second temperature of above 80° C. during the anneal process.

14. A processing system, comprising:
a processing chamber; and
a controller configured to cause a processing method to be performed in the processing chamber, the processing method comprising:
performing an etch process, comprising:
supplying a first process gas and a second process gas onto a surface of a substrate on a substrate support within a processing volume of the processing chamber for a first time duration, wherein the first process gas comprises fluorine-containing gas and the second process gas comprises nitrogen-containing gas; and
supplying the first process gas without supplying the second process gas into the processing volume of the processing chamber for a second time duration; and
performing an anneal process to sublimate by-products formed on the surface of the substrate during the etch process.

15. The processing system of claim 14, wherein
the fluorine-containing gas comprises hydrogen fluoride (HF), and
the nitrogen-containing gas gaseous comprises ammonia (NH₃).

16. The processing system of claim 14, wherein
the first time duration is between 5 seconds and 60 seconds, and
the second time duration is between 5 seconds and 60 seconds.

17. The processing system of claim 14, wherein
a flow rate of the fluorine-containing gas is between 2 sccm and 40 sccm, and
a flow rate of the nitrogen-containing gas is between 5 sccm and 50 sccm.

18. The processing system of claim 14, wherein
the processing chamber is maintained at a first pressure of between less than 1° Torr and 20° Torr during the etch process, and at a second pressure of between 1° Torr and 10° Torr during the anneal process.

19. The processing system of claim 14, wherein
the substrate support is maintained at a first temperature of 10° C. and 15° C. during the etch process, and at a second temperature of above 80° C. during the anneal process.

20. The processing system of claim 19, wherein the processing method further comprises:
cooling the substrate support to the first temperature; and
repeating the etch process and the anneal process.
